(19) United States
(12) Patent Application Publication
(10) Pub. No.: US 2020/0263294 A1
(43) Pub. Date: Aug. 20, 2020

(54) METHOD AND DEVICE FOR MONITORING A MICROWAVE PLASMA ASSISTED DEPOSITION

(71) Applicant: DIAM CONCEPT, PARIS (FR)

(72) Inventors: Alix GICQUEL, Trouville-Sur-Mer (FR); Olivier DUIGOU, Massy (FR); Thomas BIEBER, Paris (FR)

(21) Appl. No.: 16/619,741

(22) PCT Filed: Jun. 8, 2018
(86) PCT No.: PCT/FR2018/051337

§ 371 Date: Dec. 5, 2019

(30) Foreign Application Priority Data
Jun. 9, 2017 (FR) FR1755200

(51) Int. Cl. C23C 16/27; C23C 16/52; C30B 25/16; C30B 29/04

(52) U.S. Cl. CPC C23C 16/274; C30B 29/04; C30B 25/16; C23C 16/52

(57) ABSTRACT

The invention relates to a method (100) for monitoring the growth conditions of a microwave plasma-assisted deposition for diamond manufacture, said method being implemented by a monitoring device (10) comprising at least one digital image capture means (11), one digital image processing module (12), and one data processing module (13), said method including the steps of:
capturing (110) a digital color image of at least one growing diamond, using the digital image capturing means (11),
extracting (120) color characteristic values from at least one area of the captured digital image, by the digital image processing module (12), and
analyzing (130), by the data processing module (13), the extracted color characteristic values to detect a variation during the microwave plasma-assisted deposition.

The invention relates to the field of diamond synthesis by microwave plasma-assisted deposition. The invention relates to a method for monitoring a microwave plasma-assisted deposition. The invention also relates to a device for monitoring a microwave plasma-assisted deposition and a control-command system of a deposition reactor, associated with such a device.

### PREVIOUS ART

Thanks to its mechanical, optical, thermal, electronic, and chemical properties, synthetic diamond is increasingly used in industry. Thus, it is found as an essential component of many products such as optical windows, cutting tools, radiation detectors, electrodes, but also in active and passive electronics, such as a thermal drain, and it is very promising for applications in power electronics.

This multiplication of applications leads to an ever-increasing demand, as well as a search to reduce production costs and standardize production.

The one skilled in the art knows the influence and interdependence of many variables to adjust the growth conditions to the objectives pursued. During the deposition and growth phases of diamond layers, it is known to the one skilled in the art that variables and parameters such as the pressure, the power, the temperature of the one or more substrates, the concentration and composition of the injected gases, their distribution within the reactor, the electromagnetic propagation, the position and size of the one or more substrates, their distance from the plasma, generate effects on the growth of diamond layers.

While it is only possible to check the state of the diamond layers produced once the synthesis step has been completed, various tools have been put in place to monitor the deposition process and implement corrective actions, if necessary.

For example, measurements of atomic hydrogen (H) density and gas temperature (T_{g}) in a diamond deposition plasma can lead to a good knowledge of the reactor efficiency. Gas temperature measurement can be obtained from rotational temperature measurements of molecular hydrogen, and rotational temperature measurements of C₂, CH, BH molecules . . . in the excited state by OES (Optical Emission Spectroscopy) or, in the fundamental state, from the radical CH or C₂ by DFWM (Degenerate Four-Wave Mixing) or from the hydrogen atom (TALIF). Gas temperature measurements made from the emission of C₂'s Swan bands have shown, for example, very good agreement with the measurements made by TALIF (Two photon Allowed transition Laser Induced Fluorescence) on atomic hydrogen (Derkaoui et al., J. Appl. Phys. 115, 233301, 2014).

For H density measurements in a plasma, actinometry techniques (OES—Optical Emission Spectroscopy), THG (Third-Harmonic Generation), TALIF, CRDS (Cavity Ring Down Spectroscopy) are well suited.

In addition, monitoring the emission intensities by OES of some electronic transitions of the radicals CH, CH₂, C₂, CN, NH, Ar, as well as their ratio, is an interesting means for the control and command of a diamond deposition reactor (Yuzo Shigesato et al. Applied physics letters 63 (3), 314-316, 1993).

For the measurement of the density of carbonaceous species such as CH, CH₃, CH₄, C₂, C₂H₂, C₂H₄, C₂H₆, several methods have been developed: BAS (Lombardi et al. Plasma Sources Science and Technology, 13:3, 375; 2004), ultraviolet (UV) absorption (Cappelli et al., Applied physics letters 70 (8), 1052-1054, 1997; Cappelli et al., Plasma Chemistry and Plasma Processing, Vol. 20, No. 1, 2000), and infrared (IR) using laser diodes (TDLAS: Tunable Diode Laser Absorption Spectroscopy) (ROpcke, et al. Plasma Chemistry and Plasma Processing, 22:137; 2002), (Butler, High Temperature Science, 27, 183-197; 1989) or QCLs (Quantum cascade lasers) (Ma, et al. Journal of Applied Physics, 106:3, 033305-033315; 2009), LIF (Kaminski, et al. Applied Physics B: Lasers and Optics, 61:6, 585-592; 1995), DFWM (Owano, et al. Diamond and Related Materials, 2:5-7, 661-666; 1993), CRDS (Hay, et al. Journal of Materials Research, 5:11; 1990] and MS (Mass Spectrometry) (Hsu, et al. Journal of Applied Physics, 72:7, 3102-3109; 1992).

However, these methods do not directly address the behavior of the growing diamond layer, while it will have a major impact on the quality of the final product. Indeed, it has been shown that the temperature of the one or more substrates or the substrate support is a parameter of great importance in the formation of these diamond layers.

In this perspective, the temperature of the substrate or the diamond layers can generally be monitored by infrared (IR) pyrometry. The pyrometer is an optical device that detects the infrared emission of the observed element (for example, in the wavelength range of about 2 μm) and deducts the temperature therefrom. A dual wavelength system is generally used. This allows to isolate the maximum temperature measured in the target area (which corresponds to the substrate, warmer than the support) and to limit errors due to the plasma and optical window. Nevertheless, the observed object must be in the focal plane of the pyrometer, and the target area corresponds to a precise point of about one centimeter in diameter. Thus, if a new area must be targeted then it is necessary to move the pyrometer. In addition, when observing single crystal substrates during a plasma method, the plasma, the optical window through which the measurement is made, as well as the size of the substrate if it is smaller than the measurement area, can induce errors in determining the substrate temperature. In addition, pyrometric temperature measurement can be disrupted in the presence of a high energy or large plasma.

From JP H05 97581 is also known a method for diamond synthesis using vapor phase growth and growth monitoring based on excitation of the growing layers by a laser beam and analysis of light radiation emitted by a spectroscope. However, this method does not allow for continuous monitoring of all parameters or all diamond layers in formation.

Another method for producing diamonds in the vapor phase is described in document WO 2014/035344, using the presence of high-fidelity means to capture the image of diamond surface growth. However, this method only allows the surface growth of diamonds to be monitored without being able to demonstrate continuous monitoring of all variations due to changes in local growing conditions (for example, surface temperature, plasma) of the diamond layers in formation.

Thus, there is a need for new means and methods capable of addressing to the problems caused by currently available commercial reactors and in particular capable of continuously monitoring all diamond layers in formation.

### Technical Problem

The invention therefore aims to overcome the disadvantages of the prior art. In particular, the purpose of the invention is to propose a method for monitoring a microwave plasma-assisted deposition for diamond manufacture, said method allowing to monitor rapidly and in real time the influence of the values of deposition parameters on diamond layer growth and may also allow to determine new parameters for improving the growth of diamond layers and then implement them.

### BRIEF DESCRIPTION OF THE INVENTION

To this end, the invention relates to a method for monitoring the growth conditions of a microwave plasma-assisted deposition for diamond manufacture, said method being implemented by a monitoring device comprising at least one digital image capture means, one digital image processing module, and one data processing module, and said method including the steps of:
capturing a digital color image of at least one growing diamond layer, using the digital image capturing means,
extracting color characteristic values from at least one area of the captured digital image, by the digital image processing module, and
analyzing, by the data processing module, the extracted color characteristic values to detect a deviation of the growth conditions during the microwave plasma-assisted deposition.

Indeed, it has been shown by the inventors that monitoring the color of the surface of the growing diamond layers, the edge of the growing single crystal, or the surface or edge of the growth support allows the deposition method to be monitored accurately and quickly. Moreover, in addition to monitoring and detecting a deviation, this monitoring could be used to determine improved deposition parameters. Thus, for the first time, the inventors propose a method based on monitoring, preferably continuously, the color of a growing diamond layer within the resonant cavity of a deposition reactor to monitor growth. In particular, such a method can be used to identify a synthesis problem when there is, for example, a difference in color characteristic values or a deviation from the color characteristic values usually observed under these conditions. This is particularly advantageous when applied under conditions where the one or more diamond layers are positioned on a mobile growth support or when there are, within the deposition reactor, many diamond single crystals or a growing polycrystalline diamond wafer.

According to other optional and advantageous features of the method, it comprises a step of determining new values of microwave plasma-assisted deposition parameters and a control step including transmitting the new values of deposition parameters, determined by the data processing module, to a control module and modifying, by the control module, the values of plasma assisted-deposition parameters. This allows to change the growth parameters. Implementing this method allows for industrialization of the monitoring and management of the growth of diamond layers.

The invention also relates to a device for monitoring the growth conditions of a microwave-assisted plasma deposition for diamond manufacture, capable of implementing the monitoring method according to the invention, said device including:
a digital image capture means, capable of capturing a digital color image of at least one growing diamond,
a digital image processing module, capable of extracting color characteristic values from at least one area of the captured digital image, and
a data processing module, capable of detecting, from the extracted color characteristic values, a deviation of the growth conditions during the microwave plasma-assisted deposition.

Advantageously, this system is completed by a spectroscopic monitoring of the plasma and temperature measurement of diamond layers by pyrometry.

In addition, the data processing module may be able to determine new values of microwave plasma-assisted deposition parameters from the extracted color characteristic values.

The invention also relates to a microwave plasma-assisted deposition control-command system for diamond manufacture including a microwave plasma-assisted deposition reactor, as well as a monitoring device according to the invention, and a control module, configured to receive the new deposition parameter values generated by the data processing module of the monitoring device and capable of modifying the reactor deposition parameter values according to said new deposition parameter values. This system can also advantageously comprise a two-wavelength pyrometer and an emission spectroscopy device.

Other advantages and features of the invention will appear upon reading the following description given by way of illustrative and non-limiting example, with reference to the appended figures which show:

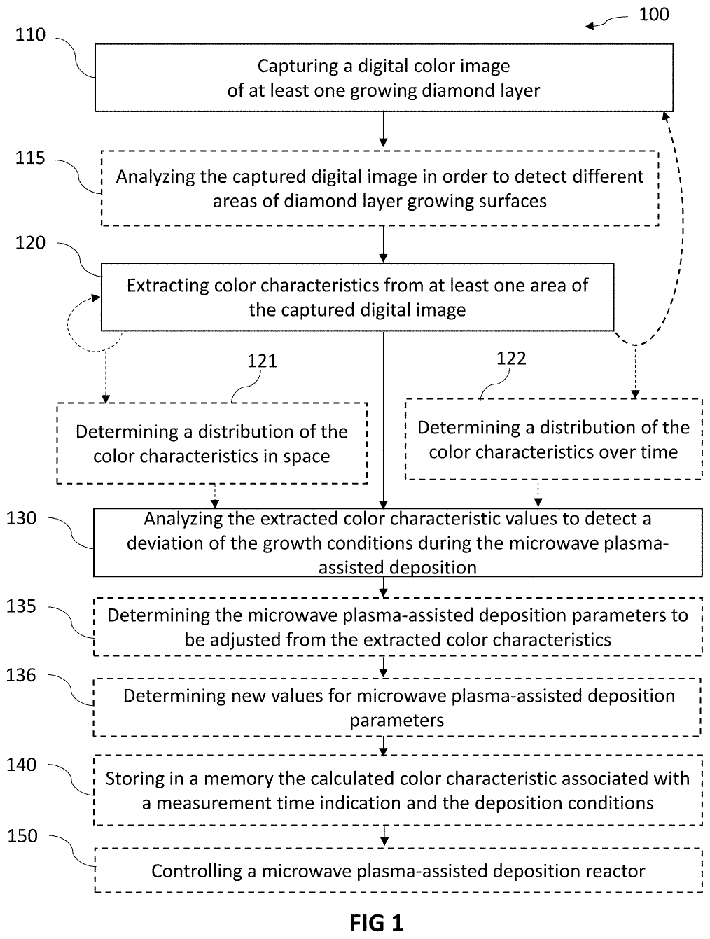

FIG. 1, a schematic view of a method for monitoring the growth of a microwave plasma-assisted diamond single crystal according to the invention. The steps framed by dotted lines are optional.

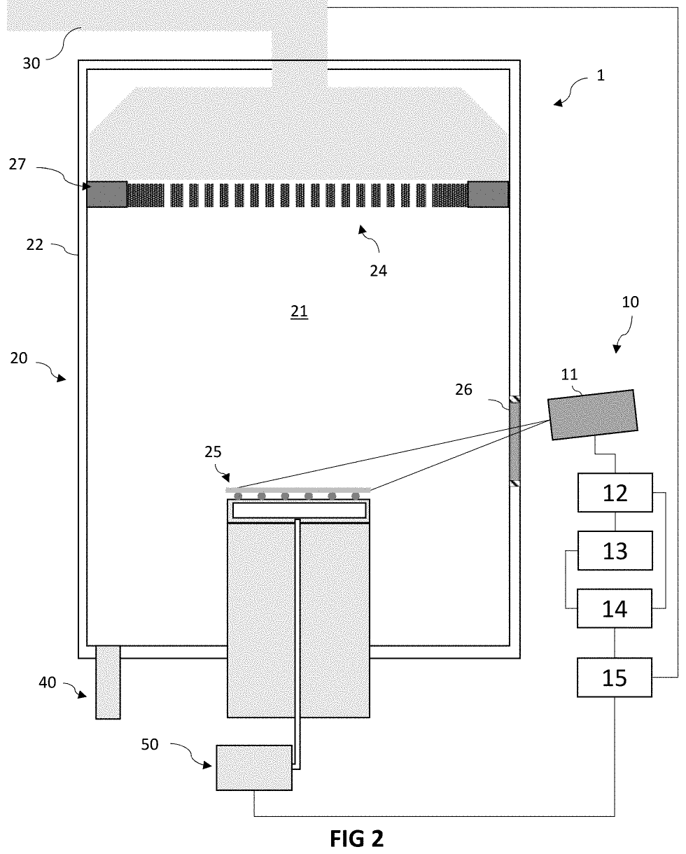

FIG. 2, a schematic cross-sectional view of a microwave plasma-assisted deposition reactor associated with a monitoring device according to the invention.

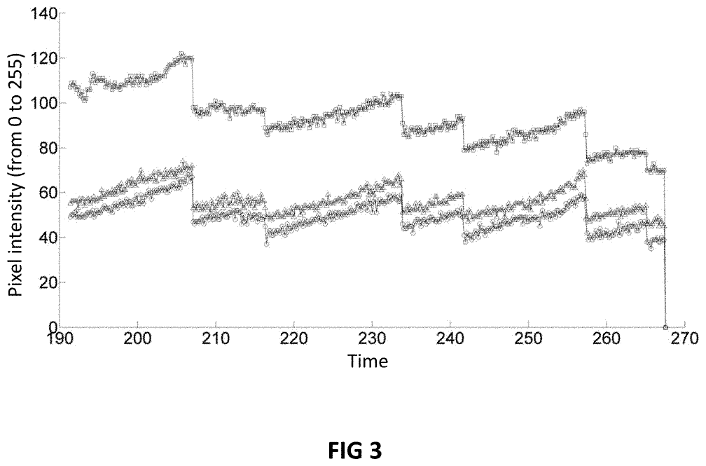

FIG. 3, a representation of the evolution of the RGB (Red Green Blue or RGB in English) value of pixels followed as a function of growth time for different areas of a growing diamond single crystal: the diamond surface (squares), the center (triangles), and the bottom (circles).

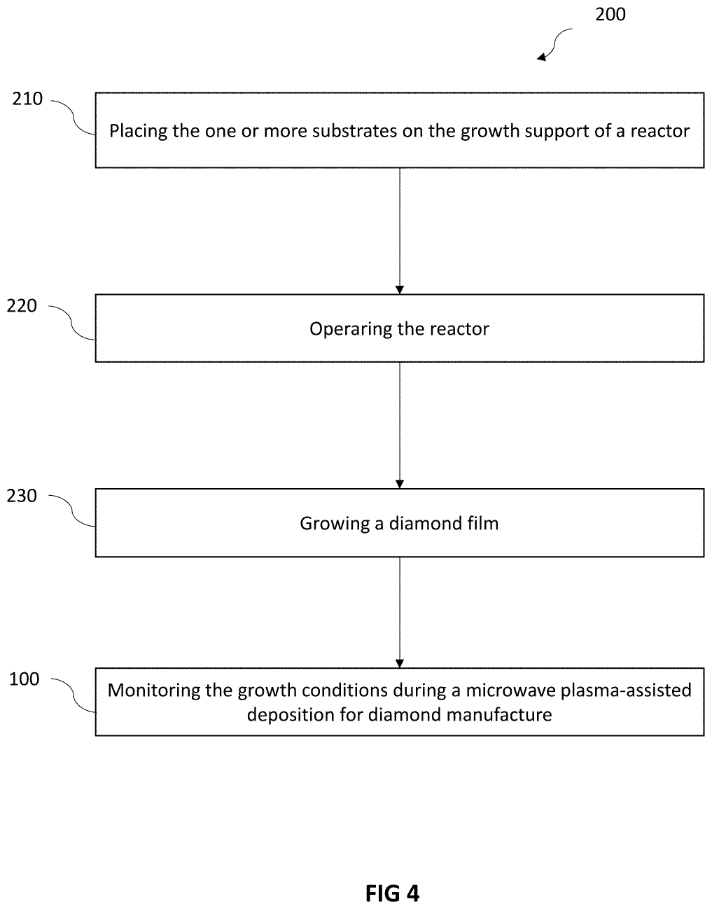

FIG. 4, a schematic view of a microwave plasma-assisted diamond deposition synthesis method according to the invention.

### DESCRIPTION OF THE INVENTION

In the remainder of the description, by “substantially identical” or “substantially equal”, is meant a value varying by less than 30% with respect to the compared value, preferably by less than 20%, even more preferably by less than 10%.

The term “growth”, within the meaning of the invention, corresponds to the one or more steps of depositing carbon in the crystalline (polycrystalline or single crystal) diamond sp3 form contributing to the production of a polycrystalline diamond layer, a diamond single crystal or nanocrystalline or ultra-nanocrystalline diamond. The growth conditions and deposition parameters represent a set of values of the variables: pressure, injected microwave power, total gas flow rate, carbonaceous precursor flow rate, impurity and dopant flow rate, composition of the resistance gas and flow rate thereof, temperatures of the one or more growing layers for a given reactor.

The term “diamond”, within the meaning of the invention, corresponds to one or more layers of polycrystalline or single crystal diamond of varying thickness, resulting from the deposition of carbon in the crystalline (polycrystalline or single crystal) diamond sp3 form. It should be noted that the reactor can also be used for growing nanocrystalline or ultra-nanocrystalline diamond, by adapting the growth conditions (temperature of the growing surface, gas composition, pressure and power conditions, . . . ).

The expression “diamond film” or “diamond layer”, within the meaning of the invention, corresponds to a layer (or film) of polycrystalline, nanocrystalline, or ultra-nanocrystalline diamond formed after nucleation on a non-diamond material surface (metal, silicon, silicon carbide, and the like), but also a single crystal or polycrystalline diamond surface. It also corresponds to obtaining single crystal diamond by thickening in height and/or width a seed diamond single crystal (or substrate) from a natural diamond single crystal, or produced by a high pressure-high temperature (HPHT) method or produced by CVD (chemical vapor deposition, plasma- or hot filament-assisted, and the like).

The term “plasma”, within the meaning of the invention, corresponds to the production, from an electrical discharge in a gas composed of a mixture, of a medium generally electrically neutral, but containing ions and electrons, as well as fragments of dissociated gaseous species, as well as stable molecules.

The term “substrate”, within the meaning of the invention, corresponds to the elements on which diamond layers or films grow. These are, for nanocrystalline or ultra-nanocrystalline polycrystalline diamond films, non-diamond (metal, silicon, silicon carbide, and the like) materials or diamond materials in the case of a multilayer growth (multi-doping or multi-property or multi-color, etc.) and for single crystal films of natural diamond single crystals or produced by a high-pressure-high temperature (HPHT) method or produced by a CVD (chemical vapor deposition, plasma- or hot filament-assisted, and the like) process.

The term “thermal resistance gas”, within the meaning of the invention, corresponds to a gas mixture composed of pure gases with very different thermal conductivities allowing, by changing the composition, to change the thermal conductivity of the mixture.

The expression “resonant cavity”, within the meaning of the invention, corresponds to a sub-portion of the volume formed by the enclosure, this sub-portion including in particular the place of formation of the plasma and the location of the one or more substrates. It is in the resonant cavity that growth is achieved. The resonant cavity depends on an assembly composed by a microwave generator, the applicator, and the impedance matching system, the gas source where the microwave energy deposition is performed within the enclosure.

The expression “growth surface”, within the meaning of the invention, corresponds to the surface located in the resonant cavity and intended for the growth of single crystal diamond or non-diamond surfaces (polycrystalline diamond growth).

The expression “growth support”, within the meaning of the invention, corresponds to an element, preferably metallic, for example made of molybdenum, intended to accommodate the one or more substrates.

In the following description, the same references are used to designate the same elements.

FIG. 1 shows a method for monitoring the growth conditions of a microwave plasma-assisted deposition for diamond manufacture according to the invention.

Indeed, according to a first aspect, the invention relates to a method 100 for monitoring the growth conditions during a microwave plasma-assisted deposition for diamond manufacture, said method including the steps of:
capturing 110 a digital color image of at least one growing diamond layer (for example, a diamond single crystal), using a digital image capturing means 11,
extracting 120 the characteristic values from at least one area of the captured digital image, by a digital image processing module 12, and
analyzing 130, by a data processing module 13, the extracted color characteristic values to detect a deviation of the growth conditions during the microwave plasma-assisted deposition.

This method is preferably implemented by a monitoring device 10 comprising at least one digital image capture means 11, one digital image processing module 12, and one data processing module 13.

The step of capturing 110 a digital color image is performed using a digital image capturing means 11. This digital image capturing means 11 can be, for example, a digital frame camera, a digital camera, or a CCD (Charge Coupled Device) sensor. This device can be equipped with complementary optics such as lenses, neutral filters, interference filters, or spectral filters. In addition, the camera is preferably calibrated beforehand, for example, for gain and saturation level, by including the effect of any filters. In particular, this calibration can be a function of the frequency of the exciter wave and the thickness of the plasma passed through, as well as the characteristics of the plasma (pressure, power, gas composition . . . ).

The capture step 110 is generally done through an observation window. Preferably, in the context of the method, the hue of the observation window is taken into account by measuring the optical absorption properties as a function of time. Indeed, as the deposition experiments progress, the hue of the observation window may change. Taking this into account may be done during the extraction step 120.

Preferably, the capture step can be followed by a step 115 of analyzing the captured digital image in order to detect different areas of growth surfaces of the diamond layer. For example, it is possible to detect different distinct areas of a same crystal (for example, surface/edge/edge height), but also several crystals, or even several areas of a wafer. More preferably, the capture step can be followed by a step 115 of analyzing the captured digital image in order to detect at least two growing diamond layers or substrates. Even more preferably, the capture step can be followed by a step 115 of analyzing the captured digital image in order to detect at least two growing diamond layers. Indeed, it is frequent that a microwave plasma-assisted deposition allows for the parallel growth of several diamond layers simultaneously. In addition, this step may also include analyzing the digitized image in order to extract the geometry of the growing diamond single crystal. The geometry of the growing diamond single crystal allows, if analyzed over time, to deduce the lateral and normal growth rates of the diamond.

Once captured, the digital color image is subject to an extraction step 120 for retrieving color characteristic values. Color characteristics are for example selected from the group consisting of: hue, saturation, brightness, brilliance, or “value”, or coded colors such as red, green, blue (in an RGB repository or RGB repository in English) or cyan, magenta, yellow, black (in a four-color repository). Preferably, the color characteristics correspond to the red, green, blue (RGB) coding values.

The area of the captured digital image from which the color characteristic values are extracted can be selected from several locations. For example, said area may correspond to the substrate support, and more particularly to the edge or surface of the substrate support, or said area may correspond to a growing diamond single crystal with more particularly the center or sides of the diamond, and this at different heights: low, middle, subsurface, or growing surface. Preferably, the area of the captured digital image from which the color characteristic values are extracted is preferably the edge or surface of the diamond. In the context of using the edge, the color considered is advantageously the color of the subsurface, which corresponds for example to a position between 0.1 mm and 1 mm below the growing surface, preferably 0.5 mm below the growing surface.

In addition, the size of the area of the captured digital image from which the color characteristic values are extracted may correspond to one pixel or several pixels. In the case of several pixels, it is possible to calculate the average or median of the color characteristic values.

In addition, the monitoring method according to the invention is intended to be used during a microwave plasma-assisted deposition and the shape and dimensions (for example, height) of the growing single crystal evolve during the deposition method. Thus, during the monitoring method according to the invention, the area of the captured digital image that is the subject of the extraction step 120 may evolve. This is the case when this area corresponds to the subsurface, the position of which evolves during the deposition method. This results in a change of some of the diamond areas that are the subject of a recovery of color characteristic values.

Advantageously, the extraction step 120 can be repeated at different times and/or locations and can then be followed by a step of determining 122 a distribution of color characteristics in time and/or space. In this case, the analysis step 130 can be performed from the distribution of the extracted color characteristics in time and/or space. Preferably, the extraction step 120 can be repeated at different times and can then be followed by a step of determining 122 a distribution of the color characteristics over time. In this case, the analysis step 130 can be performed from the distribution of the extracted color characteristics over time.

Also advantageously, the extraction step 120 can be repeated for different areas of a same captured digital image and can then be followed by a step of determining 121 a distribution of the color characteristics, in space. In this case, the analysis step 130 can be performed from the distribution of the extracted color characteristics, in space.

In the context of the microwave plasma-assisted deposition, it is possible to inject into the resonant cavity 21 one or more so-called doping gases comprising elements such as boron, sulfur, phosphorus, silicon, lithium, and beryllium. Thus, the gas inlet system 24 allows to implement a method where the gases comprise at least one dopant at a concentration equal to or greater than 0.01 ppm. The use of such so-called dopant gases allows to change the properties of the synthesized diamond. This may, for example, change its optical and/or electronic properties. Thus, the growth of diamond layers can be done in the presence of a doped gas which can have an influence on the color of the diamond on the one hand, but also more broadly on the color of the plasma within the resonant cavity 21.

Thus, advantageously, when the microwave plasma-assisted deposition is carried out in the presence of a doped process gas, the method according to the invention takes into account the influence of said doped process gas on the color characteristics extracted during the extraction step 120. It can also take into account the influence of the color of the diamond layers obtained with said doped process gas on the color characteristics extracted during the extraction step 120.

Although the method of monitoring parameter values according to the invention may be based exclusively on one or more digital color images, said method may further comprise a step of measuring the atomic hydrogen density, gas temperature, carbonaceous species density, or diamond or substrate temperature.

The gas temperature measurement can be carried out from continuous measurements. Preferably, it is obtained by rotational temperature measurements of molecules or radicals C₂, CH, BH, H₂ . . . in the state excited by OES (Rayar, et al. Journal of Applied Physics, 104:3; 2008), (Rayar, et al. Journal of Physics D: Applied Physics, 39:10, 2151; 2006). For example, in the case of C₂, it can be measured from the emission of Swan bands. Measuring the temperature of the diamond layer or substrate can be performed, for example, by IR pyrometry at two wavelengths on its edge, on its growth surface or on the substrate support.

The H density measurement can be performed preferably by OES (actinometry) techniques (Gicquel et al. 1998), TALIF, or CRDS. After calibration and for monitoring an industrial reactor, the OES method will be preferred although it does not allow absolute measurements of species density to be extracted. Thus, for the hydrogen atom and carbonaceous species, it can advantageously contribute to monitoring the ratio of different lines (I_{H}/I_{Ar}, I_{CH}/I_{C2} . . . ), controls of plasma activity, with argon being added as an impurity in the plasma (A. Gicquel et al, Journal of Applied Physics, 1998).

Similarly, the method according to the invention may further comprise a step of measuring by spectroscopy local plasma characteristics. These local plasma characteristics can be, for example, the ratio of emission lines or the gas temperature. Indeed, with the objective of controlling the growth parameters of the microwave-assisted plasma deposition reactor, it is very advantageous to couple the analysis of color characteristics with the information provided by a two-wavelength pyrometer and by optical spectroscopy (for example, emission spectroscopy). This allows in particular to determine the most relevant parameter on which to act (for example, Argon/Hydrogen ratio of the thermal resistance gas, gas flow rate, power, pressure, percentage of methane, type of dopant and its content, molecular hydrogen and methane flow rate). Thus, advantageously, the method according to the invention may further include a step of measuring values of emission intensity values of plasma species by optical spectroscopy and temperature by two-wavelength infrared pyrometry, said values being analyzed, by the data processing module 13, in parallel with the extracted color characteristic values, to detect a deviation of the growth conditions during the microwave plasma-assisted deposition. By in parallel, it should be understood that this analysis can be conducted by the data processing module 13 preferably simultaneously. However, this analysis can also be carried out sequentially, for example with a small time gap (preferably <1 minute).

Once the color characteristic values have been extracted, the method according to the invention includes an analysis step 130 for analyzing the extracted color characteristic values to detect a deviation during the microwave plasma-assisted deposition. Advantageously, the color characteristic values must remain stable throughout the experiment, except in the case where the growing conditions will be intentionally modified or modulated either periodically or permanently. The deviation is, for example, a deviation from a reference value. As will be detailed later, the reference value can be, for example, a value previously measured in the same experiment, or a value obtained in a previous experiment.

The method according to the invention may also include a step of comparing the values of the color characteristics determined with the values of the same color characteristics obtained from reference microwave plasma-assisted deposition experiments. This comparison step can, for example, comprise comparing the time evolution of the values of the color characteristic with a reference time evolution of the values of the color characteristic. Thus, there is a comparison of the kinetics of the values of the color characteristics.

This comparison step can be implemented by means of the data processing module 13 and it can be performed via known statistical methods. Preferably, this comparison step can be performed from comparison, classification, or learning models such as: neural network, Kernel, Multiple kernel learning, Support vector machine, decision trees, logistic regression, multiple regression, nearest neighbor method, and/or random forests.

More preferably, the comparison step relies on a model, trained on a dataset and configured to predict the optimal values of the microwave plasma-assisted deposition parameters. More specifically, this prediction is based on datasets containing information on the values of the deposition parameters, the values of the color characteristics, the time of measurement of these values, and the quality of the diamond layer obtained. For example, for calibration purposes, it is possible to use a dataset from a set of microwave-assisted plasma deposition experiments to define the values of the deposition parameters, the values of the color characteristics, the time of measurement of these values, and the quality of the diamond obtained, and by a binary label, for example, in the form “good diamond quality”/“poor diamond quality”. The dataset may also include multiple labels then corresponding to diamond dimensions. Preferably, the comparison step 150 includes using a supervised statistical learning model.

The invention may also include a determination step 135 for determining microwave plasma-assisted deposition parameters to be adjusted. This step is performed from the extracted color characteristic values. Advantageously, it can also be based on values of emission intensity of plasma species obtained for example by optical spectroscopy, and temperature, obtained for example by IR pyrometry at two wavelengths.

Preferably, the deposition parameters to be automatically controlled during growth (or method variables) are selected from: ratio of thermal resistance gas flows (for example, argon/dihydrogen) and total flow rate thereof, pressure, microwave power injected, carbonaceous precursor flow rate (for example, methane, ethane, diethylene . . . ), ratio of process gas component flow rates (for example, methane/dihydrogen), dopant gas flow rate. More preferably, the deposition parameters are selected from: ratio of thermal resistance gas flow rates and total flow rate thereof, pressure, microwave power injected, carbonaceous precursor flow rate, ratio of process gas component flow rates, and dopant gas flow rate.

The invention may also include a determination step 136 for calculating the new values of the microwave plasma-assisted deposition parameters. The step of determining 136 the new deposition parameter values aims to determine the deposition parameter values that will provide color characteristic values allowing for optimal growth. Advantageously, the new deposition parameter values are determined in such a way that the color characteristic values are substantially identical throughout the deposition experiment. This can be particularly appropriate when the method includes a comparison step performed from comparison, classification, or learning models.

The method according to the invention may further include a step 140 of storing in a memory the values of the determined color characteristics associated with a time indication of measurement and the growth conditions. This storage step can, for example, allow the creation of a database containing, for a multitude of microwave plasma-assisted deposition experiments, information selected from: the values of the deposition parameters, the values of the color characteristics, the measurement time of these values, the quality of the diamond obtained, and the reference of the deposition experiment.

The method according to the invention may also include a step 150 of controlling a plasma assisted-deposition reactor 20. The step 150 includes, for example, transmitting the new deposition parameter values generated by the data processing module 13 to a control module 15 and modifying by the control module 15 the deposition parameter values of the reactor 20.

According to another aspect, the invention relates to a device 10 for monitoring a microwave plasma-assisted deposition for diamond manufacture. More specifically, the monitoring device 10 according to the invention includes:
a digital image capturing means 11,
a digital image processing module 12, and
a data processing module 13.

A monitoring device 10 according to the invention is shown schematically in FIG. 2. These modules and means are distinct in FIG. 2, but the invention may provide for various types of arrangement, such as a single module combining all the functions described here. These modules can be divided into several electronic boards or combined on a single electronic board. In addition, the monitoring device 10 according to the invention may include a storage means 14.

The digital image capturing means 11 can be, for example, a digital frame camera or a digital camera. It is configured to capture a digital color image, or a plurality of digital color images, of at least one growing diamond layer. This digital image capturing means 11 can be, for example, a digital frame camera, a digital camera, or a CCD (Charge Coupled Device) sensor. This device can be equipped with complementary optics such as lenses, neutral filters, interference filters, or spectral filters.

The digital image processing module 12 is configured to receive a digital image captured by the means 11, and extract color characteristic values from at least one area of the captured digital image.

The data processing module 13 is configured to analyze the extracted color characteristic values to detect an anomaly during the microwave plasma-assisted deposition. It may also be able to determine new values of microwave plasma-assisted deposition parameters from the extracted color characteristic values.

The digital image processing module 12 and the data processing module 13 advantageously include a processor and are capable of connecting to a storage means 14.

The storage means 14 may include a transient memory and/or a non-transient memory. It is capable of storing, for example in the form of files, the one or more digital color images. It may also be capable of storing the values of the deposition parameters. In addition, the monitoring device 10 according to the invention may include, or be associated with, a remote server. For example, it is possible to access this remote server via a web interface or directly via the appropriate functions directly implemented on a control device. All communications between the one or more control devices and the remote server can be secured, for example, by HTTPS protocols and AES 512 encryption.

In addition, the monitoring device according to the invention may include a control module 15, configured to receive the new deposition parameter values generated by the data processing module 13 and capable of modifying the reactor deposition parameter values 20 depending on said new deposition parameter values. The control module 15 allows, for example, to adjust the growth parameters by varying the thermal resistance gases (for example, composition and/or flow rate).

In addition, the monitoring device 10 according to the invention may include a communication module, configured to receive and transmit information to remote systems. The communication module allows data to be transmitted over at least one communication network and can include wired or wireless communication. Preferably, communication is operated via a wireless protocol such as Wi-Fi, 3G, 4G, and/or Bluetooth. The communication module allows, for example, to send to a remote server a captured digital color image or color characteristic values of at least one area of the captured digital image. It can also be configured to send data related to the new parameter values determined. For security reasons, the communication module can be configured to only send information on data related to the new values of determined parameters and not to receive instructions for controlling the microwave plasma-assisted deposition parameters.

The method of monitoring a microwave plasma-assisted deposition according to the invention is preferably implemented in a microwave plasma-assisted deposition reactor as shown in FIG. 2. Thus, according to another aspect, the invention relates to a microwave plasma-assisted deposition system 1 for diamond manufacture including a microwave plasma-assisted deposition reactor 20 coupled to a monitoring device 10 according to the invention.

FIG. 2 illustrates a cross-sectional view of a microwave plasma-assisted deposition reactor 20 for growing diamond as can be found in the literature. The microwave plasma-assisted deposition reactor 20 for manufacturing synthetic diamond may comprise:
a resonant cavity 21, preferably cylindrical and cooled, formed, at least in part, by the cylindrical inner walls of an enclosure 22 of the reactor 20,
a process gas inlet system 24 capable of supplying process gases within the resonant cavity 21,
a microwave generator 30 configured to generate microwaves, the frequency of which is between 300 MHz and 3000 MHz,
a gas output module 40 capable of removing said gases from the resonant cavity 21,
a wave coupling module 27 capable of transferring the microwaves from the microwave generator into the resonant cavity 21, in order to allow the formation of a plasma,
a growth support 25 present in the resonant cavity 21,
an observation window 26, and
a thermal resistance gas injection module 50 capable of providing thermal resistance gases within the resonant cavity 21 and below the growth support 25.

Microwave-assisted deposition reactors allow the resonance of a standing wave created within the resonant cavity 21. This resonance is possible thanks to a precise selection of the dimensions of the resonant cavity 21 and it allows the creation of standing waves of the electric field. These reactors are configured to allow a maximum electric field within the resonant cavity 21, preferably slightly above the growth support 25.

The microwave generator 30 is configured to generate microwaves, the frequency of which is between 300 MHz and 3000 MHz. These microwaves are essential for creating standing waves of electric field within the cavity. Preferably, the microwave generator 30 is configured to generate microwaves, the frequency of which is between 400 MHz and 2700 MHz, For example, the microwave generator 30 can generate microwaves, the frequency of which is between 2300 MHz and 2600 MHz, or between 900 MHz and 1000 MHz, or between 300 MHz and 500 MHz, Preferably, the microwave generator 30 can generate microwaves, the frequency of which is substantially equal to 2450 MHz, 915 MHz, or 433 MHz. There is a large number of generators that can be used as the reactor 20. The generator used can be, for example, a microwave generator capable of delivering a power of up to 6 kW and this at a frequency substantially equal to 2450 MHz.

The microwave supply of the cavity 21, or coupling, is carried out by a wave coupling module 27 capable of transferring the microwaves from the microwave generator 30 into the resonant cavity 21 in order to allow plasma to be formed. The coupling module allows to inject, into the resonant cavity 21, the wave generated by the microwave generator 30 and to this end it includes a wave guide, a coaxial transition, and a microwave coupler to convey and guide the electromagnetic waves from the wave generator 30 into the resonant cavity 21.

The enclosure 22 of the reactor 20 can have different shapes and sizes. Preferably, the enclosure 22 has a cylindrical shape, but it can take on other shapes. The height of the enclosure 22, as measured from the base of the enclosure up to the inner surface of the wave guide, may be, for example, between 150 mm and 600 mm, preferably 200 mm and 500 mm, and more preferably between 350 mm and 450 mm. The latter dimensions are particularly preferred for operating at a microwave frequency in the range of 900 MHz to 1000 MHz. Unless indicated otherwise, the preferred dimensions or the growth conditions for a reactor 20 operating at frequencies between 300 MHz and 500 MHz may be obtained by multiplying the dimensions adapted to a reactor operating at frequencies between 900 MHz and 1000 MHz by a factor between 3.4 and 1.8. Unless indicated otherwise, the preferred dimensions or the growth conditions for a reactor 20 operating at frequencies between 2300 MHz and 2600 MHz may be obtained by dividing the dimensions adapted to a reactor 20 operating at frequencies between 900 MHz and 1000 MHz, by a factor between 2.3 and 2.9. The enclosure 20 according to the invention is generally made of metal, preferably made of aluminum or an aluminum alloy. The aluminum alloy preferably comprises at least 80%, more preferably at least 90%, and even more preferably at least 98% by weight of aluminum.

The resonant cavity 21 is formed, at least in part, by the cylindrical inner walls of the enclosure 22 of the reactor 20. For example, the resonant cavity 21 is formed for its lower part by the base of the enclosure 20. The resonant cavity 21 is preferably cylindrical. The resonant cavity 21 has a symmetry axis from the plane of the base of the enclosure to the plane of a surface of the dielectric wave injection window and is preferably adapted to a microwave resonance mode of the TM type. The base of the enclosure may have a diameter different from the diameter of the resonant cavity 21.

The reactor 20 as shown in FIG. 2 also comprises a growth support 25 located in the resonant cavity 21. This growth support 25 can, for example, form a large flat surface on which the one or more substrates are to be positioned. This growth support 25 may include projections, circles, holes, or grooves, for aligning and maintaining the one or more substrates. Alternatively, the growth support 25 includes a flat support surface on which the one or more substrates are placed.

The microwave plasma-assisted deposition reactor includes a process gas inlet system 30 capable of providing gases within the resonant cavity 21. This process gas inlet system 30 allows to implement a method where the process gases are injected towards the growth surface at a total gas flow rate of at least 100 cm³ per minute. The process gases provided within the resonant cavity 21 comprise at least one carbon source and one molecular hydrogen source. The carbon source is preferably methane (but also acetylene, ethane, or any other carbon sources). For example, for a reactor 20 operating at frequencies between 900 MHz and 1000 MHz, the gas flow rate is preferably at least 750 cm³ per minute, more preferably at least 1000 cm³ per minute. Within the resonant cavity 21, these gases are activated by the microwaves to form a plasma in the regions of high electric field. Radicals containing reactive carbon can then diffuse from the plasma to be deposited onto the one or more substrates and thus allow the diamond to grow. The process gas inlet system 30 can also allow the injection into the resonant cavity 21 of one or more so-called doping gases comprising elements such as boron, sulfur, phosphorus, silicon, lithium, and beryllium, and the like. Thus, the process gas inlet system 30 allows to implement a method where the gases comprise at least one dopant at a concentration equal to or greater than 0.01 ppm.

The gas output module 40 allows the gases present in the resonant cavity 21 to be evacuated. It comprises one or more gas outputs, preferably located in the lower part of the deposition reactor. One or more gas outputs can be located around and under the growth support 25.

Taking into account the temperature of the gas reached in the heart of the plasma (for example, more than 2500K and up to 5000K), an extremely efficient cooling of the walls of the reactor is necessary. The gas temperature of the plasma has an impact on the walls 22 which are subjected to a high heat flow. To compensate for this, a wall cooling system is generally implemented.

In addition, the monitoring method according to the invention is preferably implemented in the context of a diamond synthesis method using microwave plasma-assisted deposition. Thus, according to another aspect, the invention relates to a method 200 for diamond synthesis by microwave plasma-assisted deposition, said synthesis method 200 comprising a monitoring step corresponding to the monitoring method according to the invention.

The synthesis method 200 according to the invention further includes a step 210 of placing the one or more substrates on the growth support 25 of the reactor 20. For example, it is possible to use a silicon plate, a metal plate (Mo, W, and the like, . . . ), a polycrystalline diamond plate, diamond single crystals (natural, from a high pressure-high temperature (HPHT) method, from a CVD (chemical vapor deposition) method using the modular reactor invention or not, or single crystals from other materials (metals or the like . . . ). The diamond synthesis is preferably carried out on single crystal diamond substrates. Thus, the diamond synthesis method according to the invention preferably includes a homoepitaxial growth. The single crystal diamond substrates can have different shapes and dimensions. For example, they may be shaped like a cylinder, a cube, a parallelepiped, or the like. The dimensions may vary, for example, from 100 micrometers to several millimeters in height and several millimeters, even centimeters, in diameter or on the sides.

The synthesis method 200 according to the invention includes a step 220 of operating the reactor 20. The objective of this step is to:
generate a pressure between 0.2 hPa and 500 hPa within the resonant cavity 21,
inject microwaves, preferably in the transmission mode TM₀₁₁, and at a power between 1 kW and 100 kW (or more), depending on the type of generator used (frequency used),
inject gases, for example at a total flow rate of at least 500 cm³ per minute, the gases comprising, for example, methane and dihydrogen, and additives such as oxygen, nitrogen, boron, phosphorus, and argon, and
operate the cooling systems of the enclosure with its thermal resistance gas system, as well as a substrate cooling control system to control the temperature of the one or more growth surfaces, the gas injection system, and the substrate holder.

For a reactor operating at a frequency of 915 MHz, this allows, for example, to deliver on the substrate growth surface a surface power density of at least 0.5 W/mm², preferably at least 2 W/mm², and even more preferably at least 3 W/mm² of the substrate growth surface. Generally, the power density is less than 5 W/mm² at the substrate growth surface. This step allows to generate a plasma above the substrate growth surface and allows to initiate crystal growth. In addition, the substrate temperature is kept constant thanks to the cooling systems at a temperature between 700° C. and 1400° C., for example, except in the case of a nano- or ultra-nanocrystalline diamond growth. A description of the different growth conditions can be found in reference works (Derjaguin B. V., Journal of Crystal growth 31 (1975) 44-48; C. Wild et al, Diamond and Related Materials, 2 (1993) 158-168; Gicquel A et al. Current Applied Physics, voll Issue 6, (2001) 479; Achard J et al, Journal of Crystal Growth 284 (2005) 396-405; Butler et al, J of physics-condensed Matter, vol 21, Issue 36 (2009); Silva et al, phys. stat. sol. (a) 203, No. 12, (2006) 3049-3055; Widman C, J et al Diamond & Related Materials 64 (2016) 1-7). The surface power density can also be varied abruptly, for example by a pressure variation, to ensure abrupt variations in the composition or growth temperature (Tallaire et al., Diamond & Related Materials 51, 55-60, 2015) of the one or more substrates, for example.

The synthesis method 200 according to the invention includes a step 230 of growing (thickening/expanding) the diamond film. For polycrystalline films, this step occurs after the coalescence of the crystals and the formation of a crystalline film. Its objective is to thicken the crystalline film and improve its crystalline quality. For single crystals, expanding allows to obtain a growth area larger than the starting substrate and after normal growth, large diamond layers.

### EXAMPLES

These examples show a monitoring of the temperature evolution of a diamond during growth by studying the variation of its color (quantified via RGB coding values).

The monitoring of the RGB values during the synthesis is carried out by processing the images automatically taken by a frame camera, of the Grasshopper 3 type, at regular time intervals. This image processing is carried out by a series of automatic processes in which for each image, the RGB values of one (or more) selected pixel(s) are read and saved in a file. The RGB values of this pixel—and therefore of a specific area of the diamond—are then graphically represented as a function of the synthesis time.

In the case of the growth presented for this example, four areas are monitored: the surface of the diamond, the center of the diamond at half height, the center of the diamond at its base, and the polycrystalline diamond growing on the substrate holder. FIG. 3 shows an example of monitoring the R (red) coding values for each area over time. The sudden drops in the curves correspond to changes in growth parameters.

Thus, it is possible to observe in this FIG. 3, and more particularly on the curve corresponding to the diamond edge (center-triangles), that the monitoring of the color characteristic values allows the microwave plasma-assisted deposition to be monitored within the reactor.

It is possible with this solution to store in real time the RGB values to have a continuous control and allow a regulation of the growth parameters.

The control module 15 acting on the growth parameters, and in particular on the thermal resistance gases, allows to keep the color characteristic values (for example RGB) substantially identical during a long growth period. For example, a growth period can range from a few days to a few weeks.

1. A method for monitoring growth conditions of a microwave plasma-assisted deposition for diamond manufacture, said method being implemented by a monitoring device comprising a digital image capture means, a digital image processing module, and a data processing module, said method including the steps of:
capturing a digital color image of at least one growing diamond layer, using the digital image capturing means,
extracting color characteristic values from at least one area of the captured digital image, by the digital image processing module,
storing in a memory the extracted color characteristic values associated with respective measurement time indications and the growth conditions, and
analyzing, by the data processing module, the extracted color characteristic values to detect a deviation of the growth conditions during the microwave plasma-assisted deposition.

2. A method for monitoring growth conditions of a microwave plasma-assisted deposition for diamond manufacture, said method being implemented by a monitoring device comprising a digital image capture means, a digital image processing module, and a data processing module, said method including the steps of:
capturing a digital color image of at least one growing diamond layer, using the digital image capturing means,
extracting color characteristic values from at least one area of the captured digital image, by the digital image processing module, and
analyzing, by the data processing module, the extracted color characteristic values to detect a deviation of the growth conditions during the microwave plasma-assisted deposition,
wherein the extraction step is repeated at different times and/or locations and is followed by a step of determining a distribution of color characteristics in time and/or space, and wherein the analysis step is performed from the distribution of the extracted color characteristics in time and/or space.

3. A method for monitoring growth conditions of a microwave plasma-assisted deposition for diamond manufacture, said method being implmented by a monitoring device comprising a digital image capture means, a digital image processing module, and a data processing module, said method including the steps of:
capturing a digital color image of at least one growing diamond layer, using the digital image capturing means,
extracting color characteristic values from at least one area of the captured digital image, by the digital image processing module,
analyzing, by the data processing module, the extracted color characteristic values to detect a deviation of the growth conditions during the microwave plasma-assisted deposition, and
measuring values of emission intensity values of plasma species by optical spectroscopy and temperature by two-wavelength infrared pyrometry, said values being analyzed, by the data processing module, in parallel with the extracted color characteristic values, to detect a deviation of the growth conditions during the microwave plasma-assisted deposition.

4. The method according to claim 1, further comprising a step of determining the microwave plasma-assisted deposition parameters to be adjusted.

5. The method according to claim 1, further comprising a step of determining new values of microwave-assisted plasma deposition parameters.

6. The method according to claim 5, further comprising a control step including transmitting the new deposition parameter values determined by the data processing module to a control module and modifying, by the control module, the plasma assisted-deposition parameter values.

7. (canceled)

8. The method according to claim 1, wherein the color characteristics are selected from the group consisting of: hue, saturation, brightness, brilliance, and the colors encoded in a four-color or Red-Green-Blue repository.

9. (canceled)

10. (canceled)

11. (canceled)
